(19) United States
(12) Patent Application Publication
(10) Pub. No.: US 2014/0035058 A1
(43) Pub. Date: Feb. 6, 2014

(54) Semiconductor Devices and Methods of Manufacturing the Same

(71) Applicant: Samsung Electronics Co., Ltd., Suwon-si (KR)

(72) Inventors: Ji-Young Min, Seoul (KR); Gab-Jin Nam, Seoul (KR); Eun-Ae Chung, Hwaseong-si (KR); Jung-Dal Choi, Hwaseong-si (KR); Jin-Soak Kim, Seoul (KR); Sung-Kweon Baek, Hwaseong-si (KR)

(21) Appl. No.: 13/940,440

(22) Filed: Jul. 12, 2013

(30) Foreign Application Priority Data
Jul. 31, 2012 (KR) 10-2012-0083753

(51) Int. Cl. H01L 27/092; H01L 21/8234

(52) U.S. Cl. CPC H01L 27/092; H01L 21/823437
USPC 257/369; 438/233

(57) ABSTRACT

Methods of manufacturing a semiconductor device include forming a thin layer on a substrate including a first region and a second region and forming a gate insulating layer on the thin layer. A lower electrode layer is formed on the gate insulating layer and the lower electrode layer disposed in the second region is removed to expose the gate insulating layer in the second region. Nitrogen is doped into an exposed portion of the gate insulating layer and the thin layer disposed under the gate insulating layer. An upper electrode layer is formed on the lower electrode layer remaining in the first region and the exposed portion of the gate insulating layer. The upper electrode layer, the lower electrode layer, the gate insulating layer and the thin layer are partially removed to form first and second gate structures in the first and second regions. The process may be simplified.

### CROSS-REFERENCE TO RELATED APPLICATION

This application claims priority under 35 USC §119 to Korean Patent Application No. 10-2012-0083753 filed on Jul. 31, 2012 in the Korean Intellectual Property Office (KIPO), the entire disclosure of which is incorporated herein by reference.

### BACKGROUND

Recently, as the integration degree of semiconductor devices increases, the length of a gate electrode and the length of a channel disposed under the gate electrode have been decreased. Accordingly, a gate insulating layer having a small thickness has been used to increase the capacitance between the gate electrode and the channel, and to improve the operation of a transistor.

However, when the gate insulating layer having the small thickness is used, a time dependent dielectric breakdown (TDDB) may be generated due to a stress for a long time, particularly in an NMOS transistor, which may shorten the lifetime of a semiconductor device. For a PMOS transistor, an electron mobility in a channel region may be decreased to generate a defect concerning the increase of a threshold voltage, due to a trap phenomenon at the interface of a substrate and the gate insulating layer.

### SUMMARY

Example embodiments provide a semiconductor device having improved reliability and lifetime.

Example embodiments provide a simplified method of manufacturing the semiconductor device having improved reliability and lifetime.

According to example embodiments, there are provided methods of manufacturing a semiconductor device. In such methods, a thin layer is formed on a substrate including a first region and a second region. A gate insulating layer is formed on the thin layer. A lower electrode layer is formed on the gate insulating layer, and the lower electrode layer disposed in the second region is removed to expose the gate insulating layer in the second region. Nitrogen is doped into an exposed portion of the gate insulating layer and the thin layer disposed under the gate insulating layer. An upper electrode layer is formed on the lower electrode layer remaining in the first region and the exposed portion of the gate insulating layer. The upper electrode layer, the lower electrode layer, the gate insulating layer and the thin layer are partially removed to form first and second gate structures in the first and second regions

In example embodiments, a hard mask may be formed on the lower electrode in the first region after forming the lower electrode layer. The hard mask is removed before forming the upper electrode layer. Removing the lower electrode layer disposed in the second region may include etching the lower electrode layer using the hard mask as an etching mask. Doping nitrogen may be performed using the hard mask as a nitrogen doping mask.

In example embodiments, forming the hard mask may include forming a hard mask layer on the lower electrode layer and etching the hard mask layer through a photolithography process.

In example embodiments, doping nitrogen may include performing a plasma nitridation process or a rapid thermal nitridation process.

In example embodiments, doping nitrogen may be performed under an atmosphere including a nitrogen gas or an ammonia gas.

In example embodiments, forming the thin layer on the substrate may include thermally oxidizing a surface of the substrate.

In example embodiments, a conductive layer may be formed on the gate insulating layer before forming the lower electrode layer.

In example embodiments, removing the lower electrode layer disposed in the second region may include removing the conductive layer disposed in the second region.

In example embodiments, wherein the conductive layer disposed in the second region may be exposed after removing the lower electrode layer disposed in the second region.

In example embodiments, the lower electrode layer may be formed to include a conductive material having a work function between about 4.5 eV and about 5.2 eV.

In example embodiments, after forming the first and second gate structures, first and second spacers may be formed on side walls of the first and second gate structures, respectively. First and second impurity regions may be formed on upper portions of the substrate near the first and second gate structures, respectively, by doping impurities into the upper portions of the substrate using the first and second gate structures as impurity doping masks.

In example embodiments, doping the impurities into the upper portions of the substrate may include doping p-type impurities into the upper portion of the substrate near the first gate structure and doping n-type impurities into the upper portion of the substrate near the second gate structure.

In example embodiments, comprising before forming the thin layer, dummy gate structures and spacers may be formed in the first region and the second region of the substrate. Impurity regions may be formed at the upper portions of the substrate near the dummy gate structures by doping impurities into the upper portions of the substrate using the dummy gate structures and the spacers as impurity doping masks. The dummy gate structures may be removed.

According to example embodiments, there is provided a semiconductor device including a PMOS transistor and a NMOS transistor. The PMOS transistor may include a first gate structure and a first impurity region. The first gate structure may be disposed in a first region of a substrate including the first region and a second region. The first gate structure may include a first thin layer pattern, a first gate insulating layer pattern, a lower gate electrode and a first upper gate electrode integrated one by one. The PMOS transistor may include a second gate structure and a second impurity region. The second gate structure may be disposed in the second region of the substrate. The second gate structure may include a second thin layer pattern, a second gate insulating layer pattern and a second upper gate electrode integrated one by one. The second impurity region may be formed at the upper portion of the substrate near the second gate structure. The first thin layer pattern may include silicon oxide, and the second thin layer pattern may include silicon oxynitride.

In example embodiments, the lower gate electrode may include a conductive material having a work function between about 4.5 eV and about 5.2 eV.

According to example embodiments, a hard mask may be formed in a first region for disposing a PMOS transistor and a nitridation process may be conducted. Thus, nitrogen may be selectively doped into a thin layer and a gate insulating layer disposed in a second region for disposing an NMOS transistor. Accordingly, the thin layer of the NMOS transistor may have a large physical thickness even though having a low EOT. Thus, reliability may be improved. In addition, a negative bias temperature instability (NBTI) property may be improved through undoping nitrogen into the thin layer of the PMOS transistor.

The hard mask may be used as an etching mask in an etching process for removing a low gate electrode layer disposed in the second region and also may be used as a nitrogen doping mask while doping nitrogen into the thin layer and the gate insulating layer disposed in the second region. Accordingly, the manufacturing process may be simplified.

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

### BRIEF DESCRIPTION OF THE DRAWINGS

Example embodiments will be more clearly understood from the following detailed description taken in conjunction with the accompanying drawings. FIGS. 1 to 18 represent non-limiting, example embodiments as described herein.

FIG. 1 is a cross-sectional view illustrating a semiconductor device in accordance with some embodiments.

FIGS. 2 to 8 are cross-sectional views illustrated for explaining methods of manufacturing a semiconductor device in accordance with some embodiments.

FIGS. 9 and 10 are cross-sectional views illustrated for explaining methods of manufacturing a semiconductor device in accordance with some embodiments.

FIGS. 11 to 16 are cross-sectional views illustrated for explaining methods of manufacturing a semiconductor device in accordance with some embodiments.

FIG. 17 is a graph illustrating measured results on time dependent dielectric breakdown (TDDB) of an NMOS transistor and negative bias temperature instability (NBTI) of a PMOS transistor according to nitrogen concentration.

FIG. 18 is a block diagram for explaining systems including a semiconductor device in accordance with some embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Some embodiments of the present inventive concept are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, some embodiments will be described in detail with reference to the accompanying drawings.

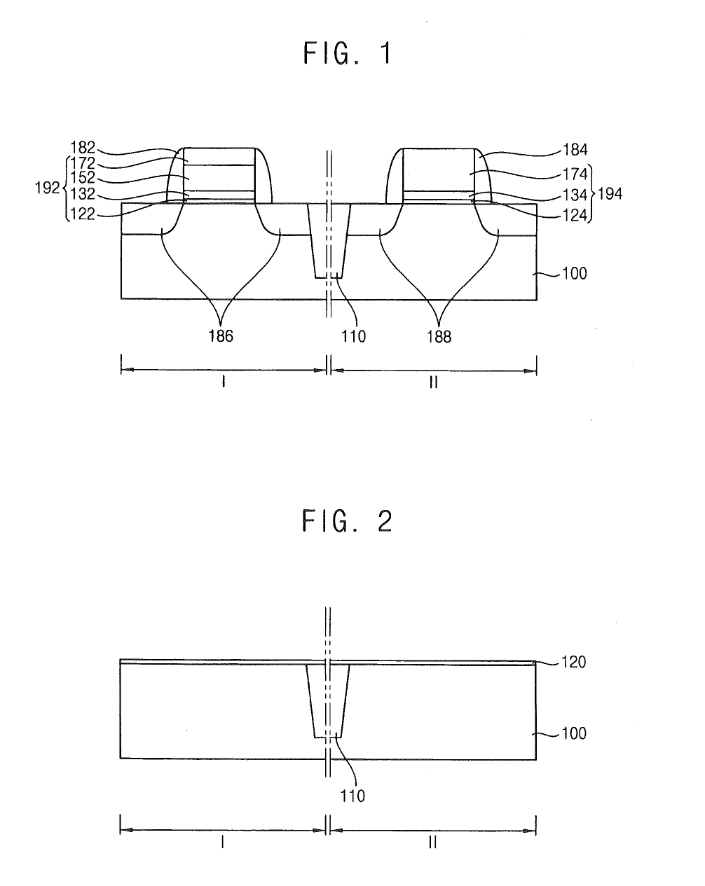

FIG. 1 is a cross-sectional view illustrating a semiconductor device in accordance with some embodiments. Particularly, the semiconductor device illustrated in FIG. 1 may include a CMOS transistor.

Referring to FIG. 1, a semiconductor device may include a first gate structure 192 and a second gate structure 194 disposed on a substrate 100. In addition, the semiconductor device may further include first and second spacers 182 and 184 on the side walls of the first and second gate structures 192 and 194, respectively, and first and second impurity regions 186 and 188 on an upper portion of the substrate 100 near the first and second gate structures 192 and 194, respectively.

The substrate 100 may include a semiconductor substrate. Particularly, the substrate 100 may include a silicon substrate, a germanium substrate, a silicon-germanium substrate, a silicon-on-insulator (SOI) substrate, a germanium-on-insulator (GOI) substrate, etc.

The substrate 100 may be divided into a first region (I) and a second region (II). In example embodiments, the first region (I) may be a PMOS transistor region, and the second region (II) may be an NMOS transistor region. In addition, an isolation layer 110 may be provided at an upper portion of the substrate 100 to define an active region of the substrate 100.

The first gate structure 192 may include a first thin layer pattern 122, a first gate insulating layer pattern 132 and a first gate electrode structure sequentially stacked on the substrate 100 in the first region (I). The second gate structure 194 may include a second thin layer pattern 124, a second gate insulating layer pattern 134 and a second gate electrode structure sequentially stacked on the substrate 100 in the second region (II). In example embodiments, the first gate electrode structure may include a lower gate electrode 152 and a first upper gate electrode 172. The second gate electrode structure may include a second upper gate electrode 174.

The first and second thin layer patterns 122 and 124 may be respectively disposed between the substrate 100 and the first and second gate insulating layer patterns 132 and 134 and may increase an interface property. The first thin layer pattern 122 may include an oxide of a material forming the substrate 100, and the second thin layer pattern 124 may include an oxynitride of a material forming the substrate 100. In example embodiments, when the substrate 100 includes silicon, the first thin layer pattern 122 may include silicon oxide (SiOx), and the second thin layer pattern 124 may include silicon oxynitride (SiON). Particularly, the second thin layer pattern 124 may include about 2 to 40 wt % of nitrogen based on the total amount of the layer. In addition, the first and second thin layer patterns 122 and 124 may have a thickness of about 5 Å to about 40 Å.

The first thin layer pattern 122 may substantially exclude nitrogen. If the first thin layer pattern 122 includes nitrogen, an interlayer trap may be formed between the substrate 100 and the first thin layer pattern 122. When the first thin layer pattern 122 of the present invention does not include nitrogen, the interlayer trap may not be formed or may be decreased. The interface trap may deteriorate the negative bias temperature instability (NBTI) determining the reliability of particularly a PMOS transistor. Thus, the PMOS transistor including the first thin layer pattern 122 excluding nitrogen may have an improved NBTI property.

Since the SiON may have a higher dielectric constant than that of SiOx, the second thin layer pattern 124 including the SiON may have a lower equivalent oxide thickness (EOT) when comparing with that including the SiOx. When considering the same EOT, the second thin layer pattern 124 including the SiON may have a greater physical thickness when comparing with that including the SiOx. Thus, the second thin layer pattern 124 may have an improved reliability.

The first and second gate insulating layer patterns 132 and 134 may be disposed on the first and second thin layer patterns 122 and 124, respectively. The first and second insulating layer patterns 132 and 134 may include an oxide having a high dielectric constant such as hafnium oxynitride (HfON), hafnium silicon oxide (HfSiₓO, HfSiO), hafnium silicon oxynitride (HfSiON), hafnium aluminum oxide (HfAlO), hafnium lanthanum oxide (HfLaO), lanthanum oxide (LaOₓ) and/or a mixture thereof. In addition, the second gate insulating layer pattern 134 may further include doped nitrogen. The doped nitrogen may be replaced with and/or cure an oxygen vacancy. Thus, the second gate insulating layer pattern 134 may have improved reliability.

The lower gate electrode 152 may be disposed on the first gate insulating layer pattern 132. The lower gate electrode 152 may include a conductive material having a work function between about 4.5 eV to about 5.2 eV. In an some embodiments, the lower gate electrode 152 may include titanium nitride (TiN). Since the lower gate electrode 152 includes a metal having a predetermined work function, the threshold voltage characteristic of the transistor including the lower gate electrode 152 may be controlled.

Although not illustrated, a conductive layer pattern may be disposed between the lower gate electrode 152 and the first gate insulating layer pattern 132. The conductive layer pattern may include titanium nitride, tantalum nitride, tungsten, ruthenium, platinum, and/or nickel, among others, and may have a relatively small thickness of about 5 Å to about 20 Å. The conductive layer pattern may be disposed between the gate insulating layer 130 and the lower gate electrode layer 150 to improve the interface property.

The first and second upper gate electrodes 172 and 174 may be disposed on the lower gate electrode 152 and the second gate insulating layer pattern 134, respectively. The first and second upper gate electrodes 172 and 174 may include a conductive metal having a relatively low resistance, such as aluminum among others.

In some embodiments, the first impurity region 186 may include p-type impurities such as boron and gallium, and the second impurity region 188 may include n-type impurities such as phosphor and/or arsenic. Accordingly, a PMOS transistor including the first gate structure 192 and the first impurity region 186 may be defined in the first region (I) of the substrate 100, and an NMOS transistor including the second gate structure 194 and the second impurity region 188 may be defined in the second region (II) of the substrate 100.

The first and second spacers 182 and 184 may include silicon nitride and/or silicon oxynitride. In some embodiments, the first and second spacers 182 and 184 may have a multi-layered structure including a silicon oxide layer and a silicon nitride layer.

On the substrate 100, an insulating interlayer (not illustrated) covering the first and second gate structures 192 and 194 and the first and second spacers 182 and 184 may be further formed. Contacts (not illustrated) making an electric contact through the insulating interlayer with the first and second impurity regions 186 and 188 and wirings (not illustrated) connected to the contacts may be further formed.

According to some embodiments, the semiconductor device may include the first gate structure 192 having the first thin layer pattern 122 substantially excluding nitrogen and the lower gate electrode 152 having predetermined work function, and the second gate structure 194 having the second thin layer pattern 124 including nitrogen. Since the first thin layer pattern 122 may substantially exclude nitrogen, the NBTI property of the PMOS transistor including the first thin layer pattern 122 may be improved. Since the first gate structure 192 includes the lower gate electrode 152 having predetermined work function, the threshold voltage of the PMOS transistor including the first gate structure 192 may be controlled. In addition, since the second thin layer pattern 124 includes nitrogen, the second thin layer pattern 124 may have an even lower EOT. The time dependent dielectric breakdown (TDDB) property of the NMOS transistor including the second thin layer pattern 124 may be improved.

FIGS. 2 to 8 are cross-sectional views illustrated for explaining methods of manufacturing a semiconductor device in accordance with some embodiments.

Referring to FIG. 2, an isolation layer 110 may be formed on a substrate 100, and a thin layer 120 may be formed on the substrate 100 and the isolation layer 110.

The substrate 100 may include a semiconductor substrate. Particularly, the substrate 100 may include a silicon substrate, a germanium substrate, a silicon-germanium substrate, an SOI substrate, and/or a GOI substrate, among others.

The substrate 100 may include a first region (I) and a second region (II). In some embodiments, the first region (I) and the second region (II) may correspond to a PMOS transistor region and an NMOS transistor region, respectively. N-type impurities or p-type impurities may be doped into the first region (I) and the second region (II). Particularly, the n-type impurities may be doped into the first region (I) of the substrate 100 to form an n-well region (not illustrated), and the p-type impurities may be doped into the second region (II) of the substrate 100 to form a p-well region (not illustrated).

After forming a first trench (not illustrated) by partially etching the upper portion of the substrate 100, an insulating layer filling the first trench may be formed on the substrate 100, and an upper portion of the insulating layer may be planarized to form the isolation layer 110.

In some embodiments, the insulating layer may be formed by using silicon oxide such as an MTO oxide, an HDP oxide, and/or a CVD oxide. The planarizing process may be conducted by means of a chemical mechanical polishing (CMP) process and/or an etch-back process until the upper surface of the substrate 100 may be exposed.

According to the formation of the isolation layer 110, the substrate 100 may be divided into a field region including the isolation layer 110 and an active region excluding the isolation layer 110.

Then, a thin layer 120 may be formed on the substrate 100 and the isolation layer 110 by means of a chemical vapor deposition (CVD) process or a thermal oxidation process. Accordingly, the thin layer 120 may include an oxide of a material forming the substrate 100. Particularly, when the substrate 100 includes silicon, the thin layer 120 may include silicon oxide (SiOx). In addition, the thin layer 120 may have a thickness of about 5 Å to about 40 Å.

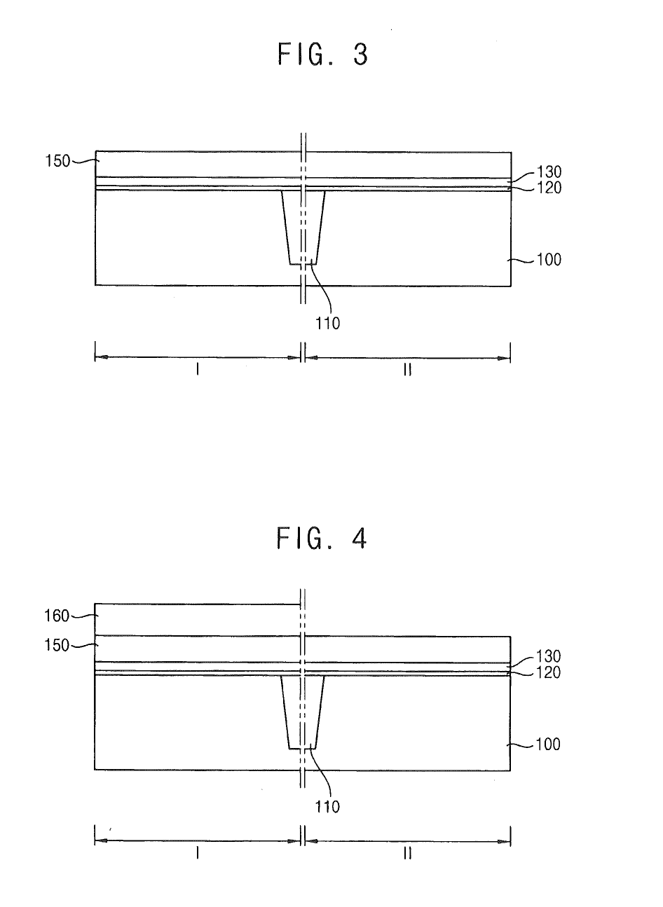

Referring to FIG. 3, a gate insulating layer 130 and a lower gate electrode layer 150 may be formed one by one on the thin layer 120.

The gate insulating layer 130 may be formed using a metal oxide having a high dielectric constant by means of a CVD process, a plasma-enhanced CVD (PECVD) process, a high density plasma CVD (HDP-CVD) process, and/or an atomic layer deposition (ALD) process, among others. Particularly, the gate insulating layer 130 may be formed using HfON, HfSiₓO, HfSiO, HfSiON, HfAlO, HfLaO, LaOₓ and/or a mixture thereof. The thickness of the gate insulating layer 130 may be determined by the dielectricity and breakdown performance of the material used.

Then, a lower gate electrode layer 150 may be formed by using a metal of a conductive metal nitride through a CVD process, a PECVD process, an ALD process, a physical vapor deposition (PVD) process, and/or a sputtering process, among others. The lower gate electrode layer 150 may be formed by using a material having a work function between about 4.5 eV and about 5.2 eV. In an example embodiment, the lower gate electrode layer 150 may include TiN.

Referring to FIG. 4, a hard mask 160 may be formed on the lower gate electrode layer 150 in the first region (I).

The hard mask 160 may be formed by forming a hard mask layer on the lower gate electrode layer 150, forming a photoresist pattern (not illustrated) on the hard mask layer and performing a photolithography process using the photoresist pattern as an etching mask. Then, the photoresist pattern may be removed.

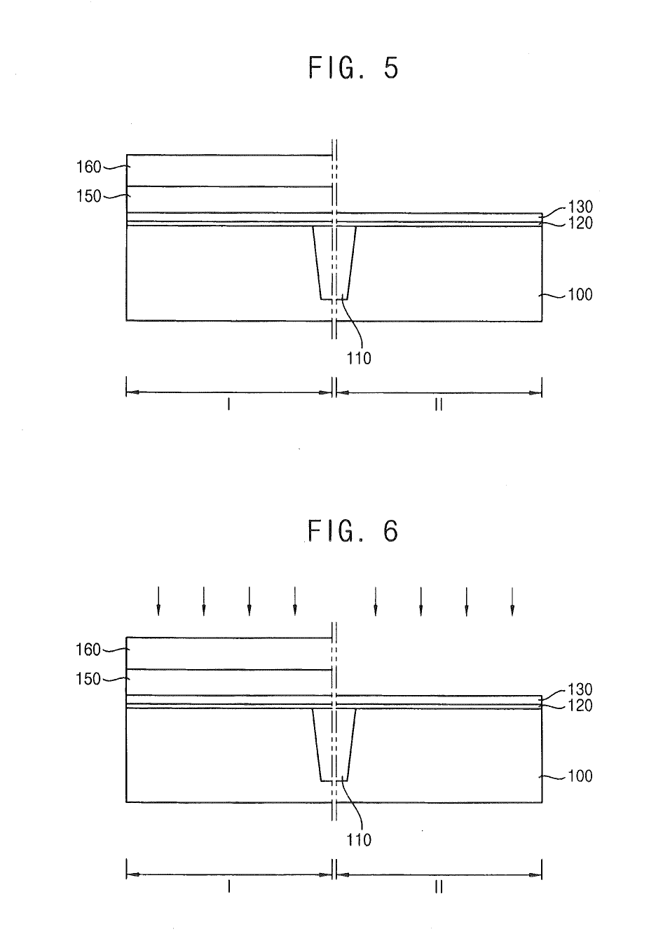

Referring to FIG. 5, the lower gate electrode layer 150 disposed in the second region (II) may be removed by using the hard mask 160 as an etching mask. Accordingly, a portion of the gate insulating layer 130 disposed in the second region (II) may be exposed.

Referring to FIG. 6, a nitridation process may be performed with respect to the exposed portion of the gate insulating layer 130 and the thin layer 120 formed thereunder.

The nitridation process may be performed by a plasma nitridation process and/or a rapid thermal nitridation process. In some embodiments, the hard mask 160 may prevent the doping of nitrogen into the gate insulating layer 130 and the thin layer 120 disposed in the first region (I). Therefore, nitrogen may be selectively doped into the exposed portion of the gate insulating layer 130 and the thin layer 120 disposed in the second region (II). That is, the hard mask 160 may also function as a nitrogen doping mask in the nitridation process. In some embodiments, through the selective nitridation process, the thin layer 120 disposed in the second region (II) may include silicon oxynitride (SiON), and the gate insulating layer 130 disposed in the second region (II) may include nitrogen doped oxide.

In some embodiments, the nitridation process may be performed through a plasma nitridation process. The plasma nitridation process may be performed by using a nitrogen (N₂) gas (or an ammonia (NH₃) gas) and a helium (He) gas at a temperature range of about 500° C. to about 1,000° C. for about 10 to about 120 seconds. Accordingly, the thin layer 120 disposed in the second region (II) may include about 2 to about 40 wt % of nitrogen based on the total amount of the thin layer 120.

Then, the hard mask 160 may be removed through an etching process and/or an ashing process.

The hard mask 160 may be used as an etching mask for removing the lower gate electrode layer 150 disposed in the second region (II) and also may be used as a nitrogen doping mask for doping nitrogen into the thin layer 120 and the gate insulating layer 130 disposed in the second region (II). Thus, the manufacturing process of the semiconductor device may be simplified.

In some embodiments, the hard mask 160 may be removed, before the nitridation process. And, the lower gate electrode layer 150 may be used as a nitrogen doping mask for doping nitrogen into the thin layer 120 and the gate insulating layer 130 disposed in the second region (II). In this case, an additional mask for doping nitrogen may not be required, so that the manufacturing process of the semiconductor device may be simplified.

Then, a thermal treatment may be additionally performed to activate the doped nitrogen. The thermal treatment may be performed by a rapid thermal oxidation (RTO), a low pressure annealing (RPA), a rapid thermal annealing (RTA), a spike RTA (sRTA), and/or a flash RTA (fRTA), among others, at a temperature range of about 700° C. to about 1,000° C. for about a few milliseconds to about 30 seconds under an oxygen atmosphere.

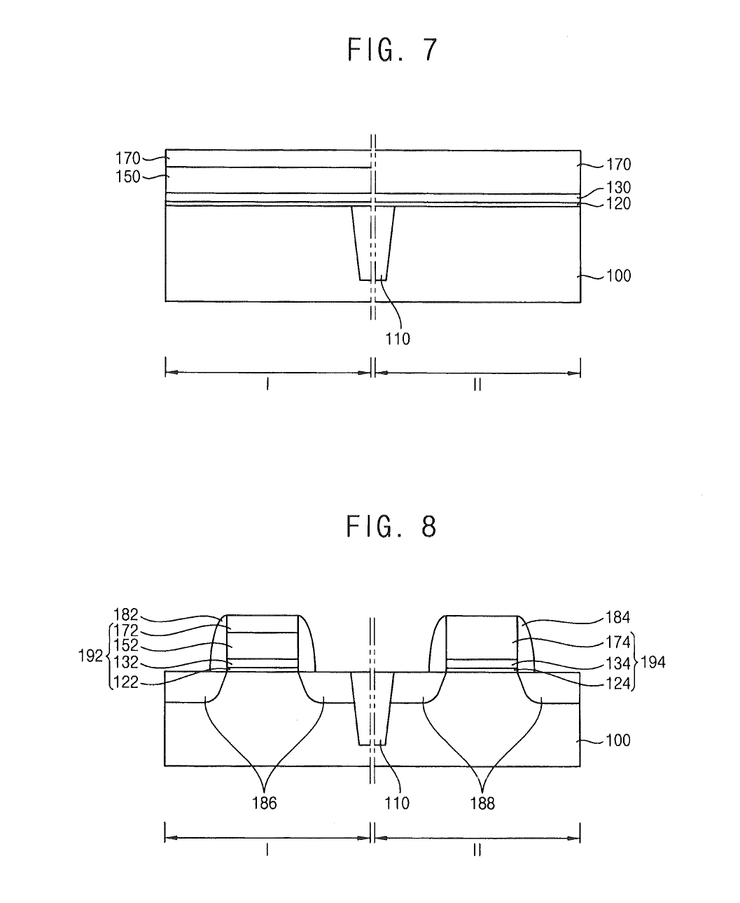

Referring to FIG. 7, an upper gate electrode layer 170 may be formed on the lower gate electrode layer 150 and the gate insulating layer 130.

The gate electrode layer 170 may be formed using a metal and/or a conductive metal compound by means of a CVD process, a PECVD process, an ALD process, a PVD process, and/or a sputtering process, among others. Then, a planarizing process may be additionally performed to form the upper gate electrode layer 170 disposed in the first region (I) and the upper gate electrode layer 170 disposed in the second region (II) having substantially the same upper surfaces. In some embodiments, the upper gate electrode layer 170 may be formed by using aluminum.

Referring to FIG. 8, integrated layers on the substrate 100 may be partially removed to form first and second gate structures 192 and 194. Impurities may be doped into the upper portions of the substrate 100 near the first and second gate structures 192 and 194 to form first and second impurity regions 186 and 188, respectively. First and second spacers 182 and 184 may be formed on the side walls of the first and second gate structures 192 and 194, respectively.

The first gate structure 192 in the first region (I) may include a first thin layer pattern 122, a first gate insulating layer pattern 132, a lower gate electrode 152 and a first upper gate electrode 172 that may be formed sequentially. The second gate structure 194 in the second region (II) may include a second thin layer pattern 124, a second gate insulating layer pattern 134 and a second upper gate electrode 174 may be formed sequentially.

The first and second impurity regions 186 and 188 may be formed by respectively doping n-type and p-type impurities into the upper portions of the substrate 100 using the first and second gate structures 192 and 194 as impurity doping masks. In some embodiments, the first impurity region 186 disposed at the upper portion of the substrate 100 near the first gate structure 192 may include p-type impurities such as boron and/or gallium, among others. The second impurity region 188 disposed at the upper portion of the substrate 100 near the second gate structure 194 may include n-type impurities such as phosphor, and/or arsenic, among others. An additional thermal treatment process may be performed to activate the p-type and the n-type impurities. Accordingly, the first gate structure 192 and the first impurity region 186 may define a PMOS transistor, and the second gate structure 194 and the second impurity region 188 may define an NMOS transistor.

Before or after forming the first and second impurity regions 186 and 188, first and second spacers 182 and 184 may be formed on the side walls of the first and second gate structures 192 and 194, respectively. The first and second spacers 182 and 184 may be formed by forming a spacer layer covering the first and second gate structures 192 and 194 on the substrate 100 and the isolation layer 110, and anisotropically etching the spacer layer. The spacer layer may be formed by using silicon nitride or silicon oxynitride through a CVD process, a PECVD process, etc.

In some embodiments, nitrogen may be selectively doped into the thin layer 120 and the gate insulating layer 130 disposed in the second region (II) by forming a hard mask 160 in the first region (I) and performing a nitridation process. The hard mask 160 may be used as an etching mask during performing an etching process to remove the lower gate electrode 150 disposed in the second region (II), and also may be used as a nitrogen doping mask while doping nitrogen into the thin layer 120 and the gate insulating layer 130. Thus, the manufacturing process may be simplified.

The thin layer 120 doped with nitrogen, that is, the second thin layer pattern 124 may include silicon oxynitride having a higher dielectricity than silicon oxide, and may have a large physical thickness while maintaining the same EOT. The nitrogen doped into the gate insulating layer 130 may be replaced with and/or cure an oxygen vacancy. Thus, the NMOS transistor including the second thin layer pattern 124 and the second gate insulating layer pattern 134 may have a good TDDB property. Since the first thin layer pattern 122 and the first gate insulating layer pattern 132 of the PMOS transistor may exclude the nitrogen, the deterioration of the NBTI property may be prevented.

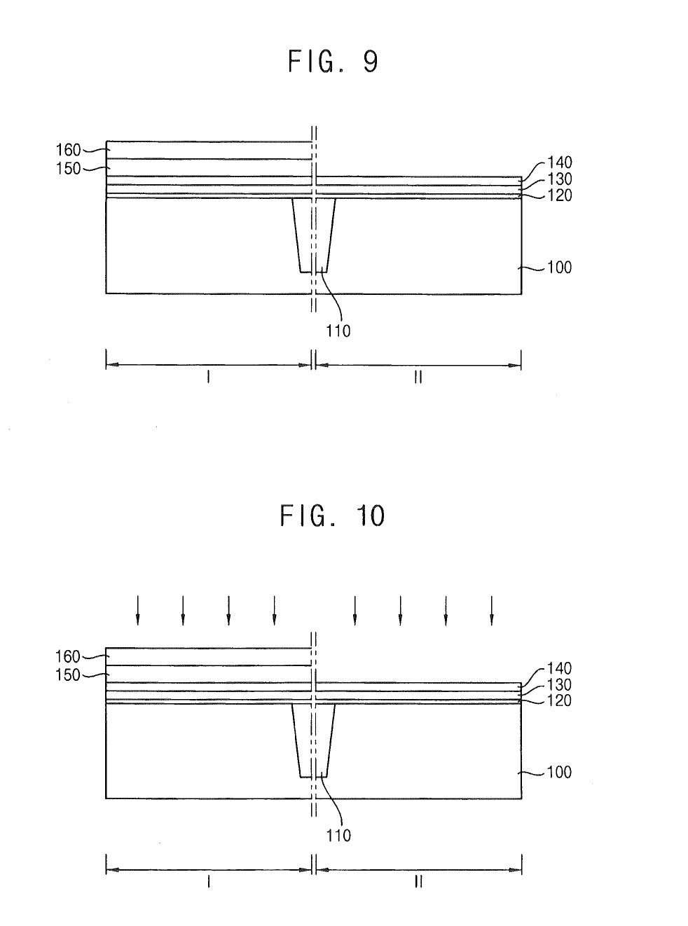

FIGS. 9 and 10 are cross-sectional views illustrated for explaining methods of manufacturing a semiconductor device in accordance with some embodiments of the inventive concept. The methods of manufacturing the semiconductor device may include substantially the same or similar processes as the processes included in the methods of manufacturing the semiconductor device explained referring to FIGS. 2 to 8. Accordingly, the same reference numerals may be designated to the same constituting elements, and detailed explanation on these elements will be omitted.

First, substantially the same or similar processes as the processes explained referring to FIGS. 2 to 4 may be performed. Only a conductive layer 140 may be formed between a gate insulating layer 130 and a lower gate electrode layer 150.

The conductive layer 140 may be formed by using a metal or a conductive metal nitride through a CVD process, a PECVD process, an ALD process, a PVD process, and/or a sputtering process, among others, on the gate insulating layer 130. Particularly, the conductive layer 140 may be formed by using titanium nitride, tantalum nitride, tungsten, ruthenium, platinum, and/or nickel, among others. In addition, the conductive layer 140 may have a relatively small thickness between about 5 Å to about 20 Å. The conductive layer 140 may be disposed between the gate insulating layer 130 and the lower gate electrode layer 150 to improve an interface property.

Referring to FIG. 9, the lower gate electrode layer 150 disposed in the second region (II) may be etched using a hard mask 160 as an etching mask. Thus, the conductive layer 140 disposed in the second region (II) may be exposed. Since the gate insulating layer 130 disposed in the second region (II) may be covered with the conductive layer 140, the damage of the gate insulating layer 130 during the etching process may be prevented.

In some embodiments, the conductive layer 140 disposed in the second region (II) may be etched while performing the etching process of the lower gate electrode layer 150 disposed in the second region (II).

Referring to FIG. 10, nitrogen may be selectively doped into the gate insulating layer 130 and the thin layer 120 disposed in the second region (II) by performing substantially the same or similar processes as the processes explained referring to FIG. 6.

The nitridation process may be performed through a plasma nitridation process or a rapid thermal nitridation process. In this case, the hard mask 160 may prevent the doping of the nitrogen into the gate insulating layer 130 and the lower gate electrode layer 150 disposed in the first region (I). In addition, the nitrogen may be selectively doped into the gate insulating layer 130 and the thin layer 120 disposed in the second region (II) by controlling the energy for plasma generation during performing the nitridation process. In some embodiments, the thin layer 120 disposed in the second region (II) may include silicon oxynitride (SiON), and the gate insulating layer 130 disposed in the second region (II) may include nitrogen doped metal oxide through the selective nitridation process. Then, the hard mask 160 may be removed through an etching process and/or an ashing process.

After removing the conductive layer 140 disposed in the second region (II), substantially the same or similar processes as explained referring to FIGS. 7 and 8 may be performed to complete the manufacturing of the semiconductor device.

In some embodiments, by forming the hard mask 160 in the first region (I) including the PMOS transistor and performing the nitridation process, the nitrogen may be selectively doped into the thin layer 120 and the gate insulating layer 130 disposed in the second region (II) including the NMOS transistor. In addition, the conductive layer 140 may prevent the damage of the gate insulating layer 130 while etching the lower gate electrode layer 150 and may improve an interface property between the lower gate electrode layer 150 and the gate insulating layer 130.

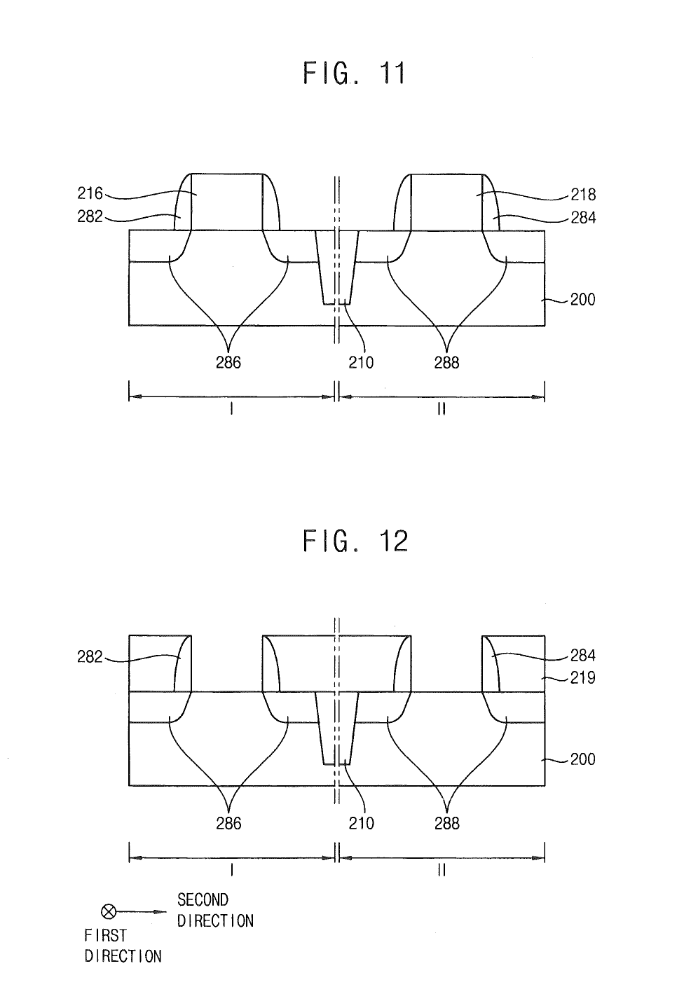

FIGS. 11 to 16 are cross-sectional views illustrated for explaining methods of manufacturing a semiconductor device in accordance with some embodiments. The methods of manufacturing the semiconductor device may include substantially the same or similar processes as the processes included in the methods of manufacturing the semiconductor device explained referring to FIGS. 2 to 8. Accordingly, the same reference numerals may be designated to the same constituting elements, and detailed explanation on these elements may be omitted.

Referring to FIG. 11, after forming an isolation layer 210 on a substrate 200, first and second dummy gate structures 216 and 218, first and second spacers 282 and 284, and first and second impurity regions 286 and 288 may be formed on the substrate 200.

The substrate 200 may include a semiconductor substrate and may be divided into a first region (I) and a second region (II). In addition, the isolation layer 210 may be formed by forming a first trench (not illustrated) by partially etching the upper portion of the substrate 200 and filling up the first trench.

First and second dummy gate structures 216 and 218 may be formed respectively in the first region (I) and the second region (II) of the substrate 200 by forming a pattern layer on the substrate 200 and the isolation layer 210, and partially removing the pattern layer. In example embodiments, the pattern layer may be formed by using silicon oxide.

The first and second spacers 282 and 284 may be formed on the side walls of the first and second dummy gate structures 216 and 218, respectively. Particularly, the first and second spacers 282 and 284 may be formed by forming a spacer layer covering the first and second dummy gate structures 216 and 218 on the substrate 200 and the isolation layer 210, and anisotropically etching the spacer layer. In some embodiments, the spacer layer may be formed by using silicon nitride or silicon oxynitride. Accordingly, the first and second dummy gate structures 216 and 218 may have an etching selectivity with respect to the first and second spacers 282 and 284.

Then, the first and second impurity regions 286 and 288 may be formed by doping n-type and p-type impurities into the upper portion of the substrate 200 by using the first and second dummy gate structures 216 and 218 and the first and second spacers 282 and 284 as impurity doping masks. In some embodiments, the first and second impurity regions 286 and 288 may be respectively disposed at the upper portion of the substrate 200 near the first and second dummy gate structures 216 and 218. Then, a thermal treatment process may be performed at a relatively high temperature to activate the p-type and n-type impurities. Since the thermal treatment process may be performed before forming the gate insulating layer 230 (see FIG. 14), the deterioration of the gate insulating layer 230, etc. by the relatively high temperature may be prevented.

Referring to FIG. 12, after forming a first insulating layer 219 filling up space between the dummy gate structures 216 and 218 and the spacers 282 and 284 on the substrate 200 and the isolation layer 210, the dummy gate structures 216 and 218 may be removed.

Particularly, the first insulating layer 219 may be formed on the substrate 200 and the isolation layer 210 so as to cover the dummy gate structures 216 and 218 and the spacers 282 and 284. Then, the upper portion of the first insulating layer 219 may be planarized until exposing the upper surfaces of the dummy gate structures 216 and 218. In some embodiments, the planarization process may be performed by a CMP process.

Then, the dummy gate structures 216 and 218 may be removed through a wet etching process using an etching solution having an etching selectivity with respect to the first and second spacers 282 and 284.

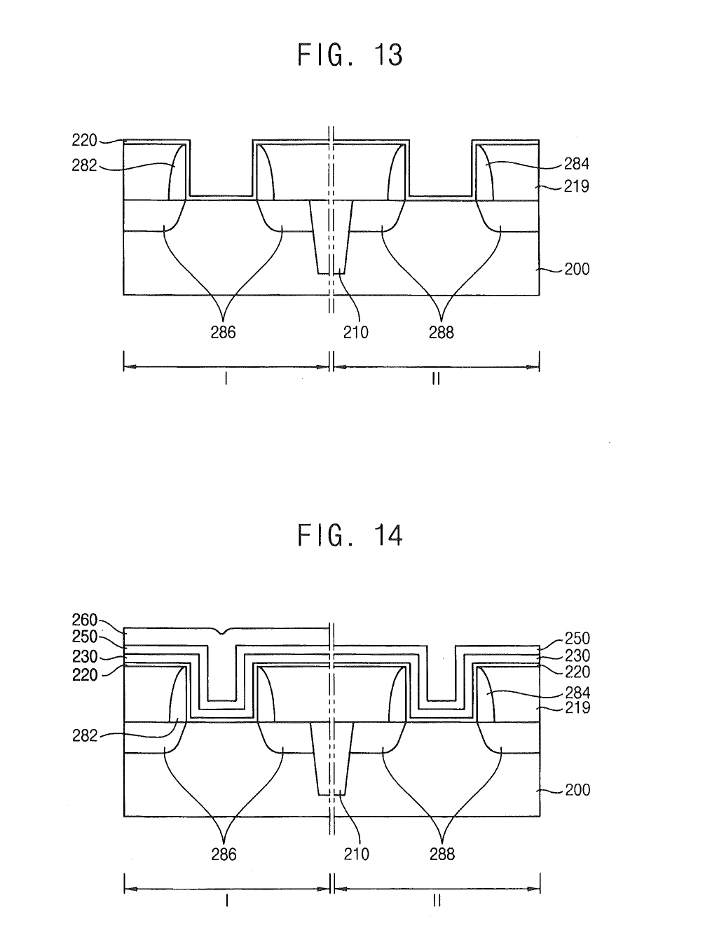

Referring to FIG. 13, a thin layer 220 may be formed on the substrate 200, on the side wall of the spacers 282 and 284, and on the first insulating layer 219.

The thin layer 220 may be formed on the substrate 200 and the first insulating layer 219, and the side wall of the first and second spacers 282 and 284 through a thermal oxidation process and/or a CVD process. In some embodiments, when the substrate 200 includes silicon, the thin layer 220 formed on the substrate 200 may include silicon oxide (SiOx) and may have a thickness between about 5 Å to about 40 Å.

Referring to FIG. 14, a gate insulating layer 230 and a lower gate electrode layer 250 may be formed one by one on the thin layer 220. Then, a hard mask 260 may be formed in the first region (I) of the lower gate electrode layer 250.

The gate insulating layer 230 and the lower gate electrode layer 250 may be formed through substantially the same or similar processes explained referring to FIG. 3. The hard mask 260 may be formed through substantially the same or similar processes explained referring to FIG. 4.

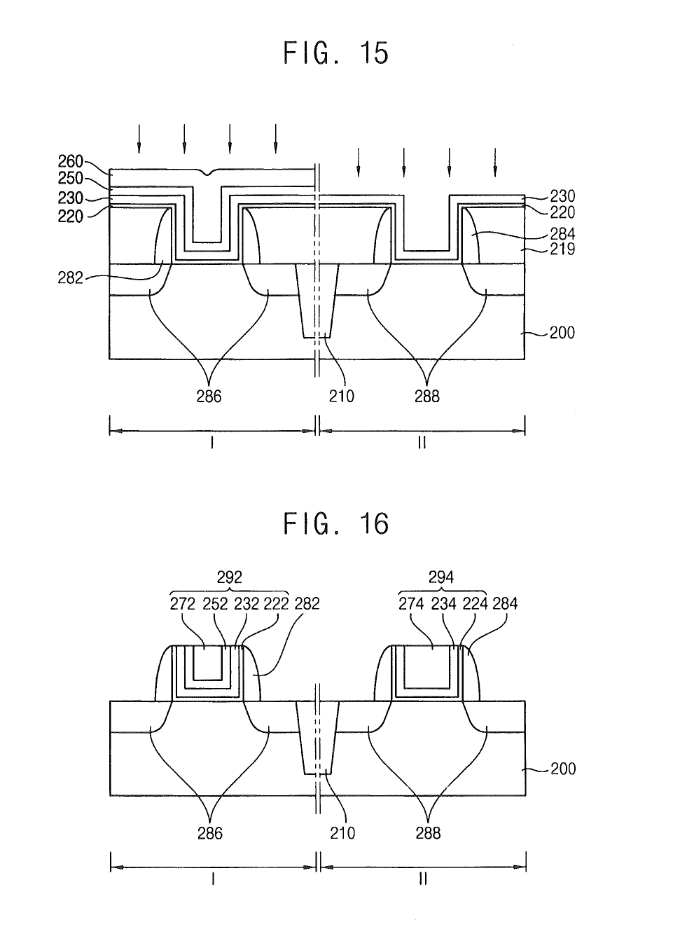

Referring to FIG. 15, after removing the lower gate electrode layer 250 disposed in the second region (II), nitrogen may be doped through performing a nitridation process with respect to an exposed gate insulating layer 230 and the thin layer 220.

The lower gate electrode layer 250 may be partially removed through an etching process using the hard mask 260 as an etching mask. Thus, the gate insulating layer 230 disposed in the second region (II) of the substrate 200 may be exposed.

The nitridation process may be performed by substantially the same or similar processes as the nitridation process explained referring to FIG. 6. That is, the hard mask 260 may function as a nitrogen doping mask while performing the nitridation process. Through the selective nitridation process, the thin layer 220 disposed in the second region (II) may include silicon oxynitride (SiON), and the gate insulating layer 230 disposed in the second region (II) may include a nitrogen doped metal oxide.

Then, the hard mask 260 may be removed through an etching process and/or an ashing process.

Referring to FIG. 16, an upper gate electrode layer may be formed on the lower gate electrode layer 250 and the gate insulating layer 230. The upper portions of the thin layer 220, the gate insulating layer 230, the lower gate electrode layer 250 and the upper gate electrode layer may be planarized to form first and second gate structures 292 and 294.

The upper gate electrode layer may be formed by using a metal or a conductive metal compound through a CVD process, a PECVD process, an ALD process, a PVD process, and/or a sputtering process, among others. In this case, the upper gate electrode layer may be formed to completely fill up the space between the first spacers 282 and the space between the second spacers 284.

The first and second gate structures 292 and 294 may be formed by planarizing the upper portions of the thin layer 220, the gate insulating layer 230, the lower gate electrode layer 250 and the upper gate electrode layer until the upper portion of the first insulating layer 219 may be exposed. Accordingly, the first gate structure 292 may include a first thin layer pattern 222, a first gate insulating layer pattern 232, a lower gate electrode 252 and a first upper gate electrode 272 formed one by one on the substrate 200 and on the inner side wall of the first spacer 292. The second gate structure 294 may include a second thin layer pattern 224, a second gate insulating layer pattern 234 and a second upper gate electrode 274 integrated one by one on the substrate 200 and on the inner side wall of the second spacer 294.

Then, the first insulating layer 219 may be removed through an etching process.

Accordingly, the first gate structure 292, the first spacer 282 and the first impurity regions 286 may define a PMOS transistor, and the second gate structure 294, the second spacer 284 and the second impurity regions 288 may define an NMOS transistor.

In some embodiments, the first and second impurity regions 286 and 288 may be formed before forming the first and second insulating layer patterns 232 and 234. Thus, the damage of the first and second insulating layer patterns 232 and 234 while performing a thermal treatment process to form the first and second impurity regions 286 and 288 at a relatively high temperature may be prevented.

In addition, through forming a hard mask 260 in the first region (I) including the PMOS transistor and performing a nitridation process, nitrogen may be selectively doped into the thin layer 220 and the gate insulating layer 230 disposed in the second region (II) including the NMOS transistor. The nitrogen doped thin layer 220, that is, the second thin layer pattern 224 may include silicon oxynitride having a higher dielectricity than silicon oxide, and may have a greater physical thickness while maintaining the same EOT. Thus, the NMOS transistor including the second thin layer pattern 224 and the second gate insulating layer pattern 234 including nitrogen may have a good TDDB property. Meantime, since the first thin layer pattern 222 and the first gate insulating layer pattern 232 of the PMOS transistor excludes the nitrogen, the deterioration of the NBTI property may be prevented.

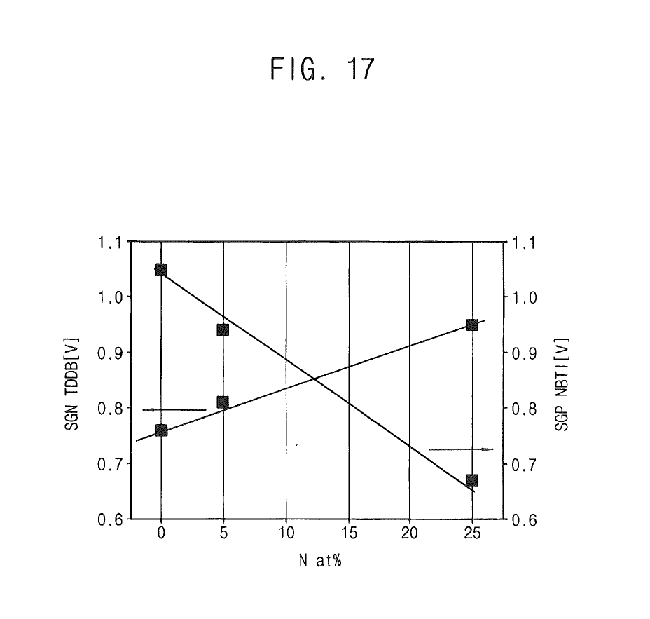

FIG. 17 is a graph illustrating measured results on time dependent dielectric breakdown (TDDB) of an NMOS transistor and negative bias temperature instability (NBTI) of a PMOS transistor according to nitrogen concentration.

In the graph, the x-axis represents nitrogen concentration of a thin layer pattern (disposed between a substrate and a gate insulating layer pattern), and y-axis represents a measured TDDB property of an NMOS transistor and a measured NBTI property of a PMOS transistor by voltage. The TDDB property may represent the deteriorating and breakage property of the gate insulating layer according to the lapse of time and may have a significant meaning in the NMOS transistor of which lifetime may be decreased due to the breakage of the gate insulating layer. The NBTI property may represent a deteriorating property of a gate-induced drain leakage (GIDL) when applying a temperature and a negative bias, and may have a significant meaning in the PMOS transistor of which reliability may be mainly generated at the negative bias.

The TDDB property was obtained by measuring a voltage value when a break down was taken place while applying a constantly increasing voltage to an NMOS transistor including a gate insulating layer having the same EOT according to time. The NBTI property was obtained by measuring a voltage value when a GIDL value exceeded a constant reference value while changing the voltage at about 125° C.

As illustrated in FIG. 17, when the nitrogen concentration of the thin layer pattern increases, the voltage value illustrating the TDDB property of the NMOS transistor may increase while the voltage value illustrating the NBTI property of the PMOS transistor may decrease. A good reliability was obtained when the nitrogen concentration of the thin layer was increased in the NMOS transistor, while a good reliability was obtained when the nitrogen concentration of the thin layer was decreased in the PMOS transistor.

In the PMOS transistor, as the nitrogen concentration of the thin layer increases, the NBTI property was considered to be increased by forming an interlayer trap between the thin layer and the substrate due to nitrogen.

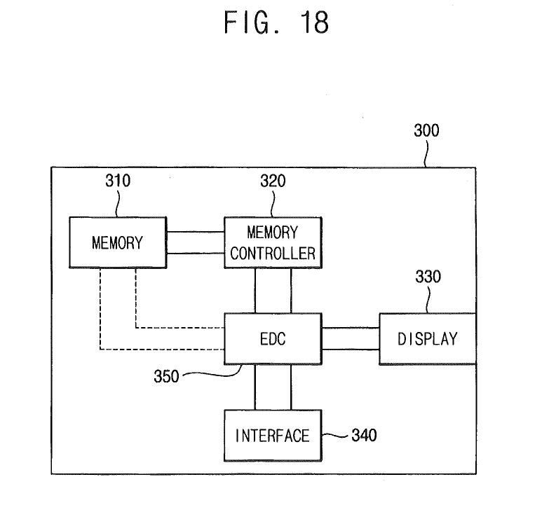

FIG. 18 is a block diagram for explaining a system 300 including a semiconductor device in accordance with some embodiments.

Referring to FIG. 18, a system 300 may include a memory 310, a memory controller 320 controlling the operation of the memory 310, a displaying part 330 outputting information, an interface 340 receiving information and a main processor 350 controlling the above described parts. The memory 310 may be a semiconductor device in accordance with some embodiments. The memory 310 may be directly connected to the main processor 350 or through a bus. The system 300 may be applied to a computer, a portable computer, a laptop computer, a personal portable terminal, a tablet, a cellular phone, a digital music player, etc.

According to methods of manufacturing a semiconductor device in accordance with some embodiments, a hard mask may be formed in a first region for disposing a PMOS transistor and a nitridation process may be performed. Thus, nitrogen may be selectively doped into a thin layer and a gate insulating layer disposed in a second region for disposing an NMOS transistor. Accordingly, the thin layer of the NMOS transistor may have a large physical thickness even though having a low EOT. Thus, reliability may be improved. In addition, an NBTI may be improved through undoping nitrogen into the thin layer of the PMOS transistor.

The hard mask may be used as an etching mask in an etching process for removing a low gate electrode layer disposed in the second region and also may be used as a nitrogen doping mask while doping nitrogen into the thin layer and the gate insulating layer disposed in the second region. Accordingly, the manufacturing process may be simplified.

The foregoing is illustrative of some embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor device, comprising:
forming a thin layer on a substrate including a first region and a second region;
forming a gate insulating layer on the thin layer;
doping nitrogen into a portion of the gate insulating layer and a portion of the thin layer disposed under the gate insulating layer in the second region; and
forming first and second gate structures in the first and second regions, respectively.

2. The method according to claim 1, wherein forming the first and second gate structures comprises:
forming a lower electrode layer on the gate insulating layer in the first region; and
forming an upper electrode layer on the lower electrode layer in the first region and the gate insulating layer in the second region.

3. The method according to claim 2, wherein forming the lower electrode layer on the gate insulating layer in the first region comprises:
forming the lower electrode layer on the gate insulating layer; and
removing a portion of the lower gate electrode layer that corresponds to the second region to expose a portion of the gate insulating layer in the second region.

4. The method according to claim 2, wherein forming the first and second gate structures further comprises partially removing the upper electrode layer, the lower electrode layer, the gate insulating layer and the thin layer to form first and second gate structures in the first and second regions, respectively.

5. The method according to claim 2, further comprising forming a hard mask on the lower electrode in the first region after forming the lower electrode layer,
and further comprising removing the hard mask before forming the upper electrode layer,
wherein removing the lower electrode layer disposed in the second region includes etching the lower electrode layer using the hard mask as an etching mask,
and wherein doping nitrogen is performed using the hard mask as a nitrogen doping mask.

6. The method according to claim 5, wherein forming the hard mask comprises:
forming a hard mask layer on the lower electrode layer; and
etching the hard mask layer through a photolithography process.

7. The method according to claim 3, further comprising forming a conductive layer on the gate insulating layer before forming the lower electrode layer.

8. The method according to claim 7, wherein removing the lower electrode layer disposed in the second region further comprises removing the conductive layer disposed in the second region.

9. The method according to claim 7, wherein the conductive layer disposed in the second region is exposed after removing the lower electrode layer disposed in the second region.

10. The method according to claim 2, wherein the lower electrode layer is formed to include a conductive material having a work function between about 4.5 eV and about 5.2 eV.

11. The method according to claim 1, wherein doping nitrogen includes performing a plasma nitridation process and/or a rapid thermal nitridation process.

12. The method according to claim 1, wherein doping nitrogen is performed under an atmosphere including a nitrogen gas or an ammonia gas.

13. The method according to claim 1, wherein forming the thin layer on the substrate comprises thermally oxidizing a surface of the substrate.

14. The method according to claim 1, after forming the first and second gate structures, further comprising,
forming first and second spacers on side walls of the first and second gate structures, respectively; and
forming first and second impurity regions on upper portions of the substrate near the first and second gate structures, respectively, by doping impurities into the upper portions of the substrate using the first and second gate structures as impurity doping masks.

15. The method according to claim 14, wherein doping the impurities into the upper portions of the substrate comprises:
doping p-type impurities into the upper portion of the substrate near the first gate structure; and
doping n-type impurities into the upper portion of the substrate near the second gate structure.

16. The method according to claim 1, further comprising, before forming the thin layer:
forming dummy gate structures and spacers in the first region and the second region of the substrate;
forming impurity regions at the upper portions of the substrate near the dummy gate structures by doping impurities into the upper portions of the substrate using the dummy gate structures and the spacers as impurity doping masks; and
removing the dummy gate structures.

17. A semiconductor device, comprising:
a semiconductor substrate comprising a first region and a second region;
a PMOS transistor including a first gate structure and a first impurity region, a first gate structure being disposed in the first region of the substrate, the first gate structure including a first thin layer pattern, a first gate insulating layer pattern, a lower gate electrode and a first upper gate electrode, the first impurity region being formed at an upper portion of the substrate near the first gate structure; and
a NMOS transistor including a second gate structure and a second impurity region, the second gate structure being disposed in the second region of the substrate, the second gate structure including a second thin layer pattern, a second gate insulating layer pattern and a second upper gate electrode, the second impurity region being formed at the upper portion of the substrate near the second gate structure,
wherein the first thin layer pattern includes a first nitrogen concentration and the and the second thin layer pattern includes a second nitrogen concentration that is greater than the first nitrogen concentration.

18. The semiconductor device according to claim 17, wherein the lower gate electrode includes a conductive material having a work function between about 4.5 eV and about 5.2 eV.

19. The semiconductor device according to claim 17, wherein NMOS transistor including the second thin layer pattern has a voltage value corresponding to time dependent dielectric breakdown that is positively correlated with a nitrogen concentration of the second thin layer pattern.

20. The semiconductor device according to claim 17, wherein PMOS transistor including the first thin layer pattern has a voltage value corresponding to negative bias temperature instability that is negatively correlated with a nitrogen concentration of the first thin layer pattern.
